(19) United States
(12) Patent Application Publication
(10) Pub. No.: US 2014/0224320 A1
(43) Pub. Date: Aug. 14, 2014

(54) SOLAR CELL MODULE

(71) Applicant: SANYO ELECTRIC CO., LTD., Osaka (JP)

(72) Inventor: Wataru SHINOHARA, Gifu (JP)

(73) Assignee: SANYO ELECTRIC CO., LTD., Osaka (JP)

(21) Appl. No.: 14/254,469

(22) Filed: Apr. 16, 2014

Related U.S. Application Data
(63) Continuation of application No. PCT/JP2012/006944, filed on Oct. 30, 2012.

(30) Foreign Application Priority Data
Oct. 31, 2011 (JP) 2011-238309

(51) Int. Cl. H01L 31/02

(52) U.S. Cl. CPC H01L 31/02013
USPC 136/256

(57) ABSTRACT

A solar cell module includes a translucent member placed at a light-receiving side, a back-side member provided in such a position as to face the translucent member, a photovoltaic device provided between the translucent member and the back-side member, an electrode, connected to the photovoltaic device, which is provided between the translucent member and the back-side member, a current extraction member, provided on an outer surface of the back-side member, which is provided in such a manner as to electrically conduct to the electrode, and a sealing member filled in a region where the current extraction member and the back-side member face each other. The back-side member has a through-hole, and the current extraction member is secured to the back-side member by the sealing member so that the current extraction member can cover the entire through-hole.

### CROSS-REFERENCE TO RELATED APPLICATIONS

This application is based upon and claims the benefit of priority from the prior Japanese Patent Application No. 2011-238309, filed on Oct. 31, 2011, and International Patent Application No. PCT/JP2012/006944, filed on Oct. 30, 2012, the entire content of each of which is incorporated herein by reference.

### BACKGROUND OF THE INVENTION

1. Field of the Invention

The present invention relates to a solar cell module.

2. Description of the Related Art

The so-called solar cells used as photoelectric conversion devices for converting light energy into electric energy have been strenuously developed so far in many areas. The solar cells can directly convert the sunlight, which is a clean and inexhaustible energy source, and is therefore expected as a new energy source.

In many cases, the solar cell is modularized and has an output terminal through which the generated electricity is outputted to the external. Such an output terminal is often provided in such a manner that normally the output terminal protrudes on a side of a rear surface opposite to a light-receiving surface of the sunlight. Also, proposed is a solar cell module where a housing section for housing such an output terminal is provided in a center of the rear surface of a solar cell panel (see Reference (1) in the following Related Art List, for instance).

The aforementioned housing section in the solar cell module holds and encloses a solder joint, which electrically connects a terminal-side internal lead wire and an external lead wire, a diode for use with backflow prevention, and so forth. Here, the terminal-side internal lead wire is sealed off within the solar cell panel, and the external lead wire is waterproof-coated. Also, the components held and enclosed by the housing section are sealed off by a filler adhesive such as silicone resin.

### RELATED ART LIST

(1) Japanese Unexamined Patent Publication No. Hei09-279789.

The components, in a conventional solar cell panel, which are exposed to the outdoor environment are glass, serving as a substrate, a terminal box, cables and so forth. Among these components exposed thereto, the durability of the terminal box and the cables where the resin material is often used are lower than that of glass. Thus these components deteriorate more quickly than glass does, when used outdoors for a long period time. Furthermore, the adhesives are used to secure a connection box and the like by using potting and therefore it is difficult to replace the connection box and the like when those components have deteriorated.

Accordingly, when a desired output is no longer obtained, from the solar cell panel, due to a degradation over time in such the terminal box and the like, the entire solar cell panel must be replaced anew even though an electric power generation unit such as a photovoltaic device works normally then. Thus, the components, such as the terminal box, which are hard to be detached/attached, may possibly contribute to causing the life of the solar cell panel to be reduced.

### SUMMARY OF THE INVENTION

The present invention has been made in view of the foregoing circumstances, and a purpose thereof is to provide a technology for extending service life of a solar cell module.

In order to resolve the above-described problems, a solar cell module according to one embodiment of the present invention includes: a translucent member disposed at a light-receiving side of the solar cell module; a back-side member provided in such a position as to face the translucent member; a photovoltaic device provided between the translucent member and the back-side member; a current-collecting wiring connected to the photovoltaic device, the current-collecting wiring being provided between the translucent member and the back-side member; a conductive member provided in such a manner as to electrically conduct to the current collecting wiring, the conductive member being provided on an outer surface of the back-side member; and a sealing member filled in a region where the conductive element and the back-side member face each other. The back-side member has a through-hole, and the conductive member is fixed to the back-side member by the sealing member in such a manner as to cover the entire through-hole.

### BRIEF DESCRIPTION OF THE DRAWINGS

Embodiments will now be described by way of examples only, with reference to the accompanying drawings which are meant to be exemplary, not limiting, and wherein like elements are numbered alike in several Figures in which:

FIG. 1 is a plane view of a solar cell module, according to a first embodiment, as viewed from a back side opposite to a light receiving surface thereof;

FIG. 2 is an exploded view of a cross section thereof taken along the line A-A of FIG. 1 near a terminal box;

FIG. 3 is an exploded view of a cross section thereof taken along the line B-B of FIG. 1 near a terminal box;

FIG. 4 is a top view of a current extraction member as viewed from an arrow C shown in FIG. 2;

FIG. 5 is a diagram schematically showing a cross section of an exemplary photovoltaic element;

FIG. 6 is a partial cross-sectional view of a solar cell module, according to a second embodiment, near a current extraction member;

FIG. 7 is a partial cross-sectional view of a solar cell module, according to a third embodiment, near a current extraction member;

FIG. 8 is a partial cross-sectional view of a solar cell module, according to a fourth embodiment, near a current extraction member;

FIG. 9 is a cross-sectional view showing a structure of a solar cell module according to a fifth embodiment; and

FIG. 10 is a plane view showing a light-receiving surface of a solar cell module according to a fifth embodiment.

### DETAILED DESCRIPTION OF THE INVENTION

The invention will now be described by reference to the preferred embodiments. This does not intend to limit the scope of the present invention, but to exemplify the invention.

Hereinbelow, the preferred embodiments will be described with reference to the accompanying drawings. Note that in all of the Figures the same reference numerals are given to the same components and the description thereof is omitted as appropriate.

The scale reduction and the form of each layer and each component shown in each of the following Figures are conveniently set for the ease of explanation and should not be construed in a limited extent unless otherwise explicitly specified.

### First Embodiment

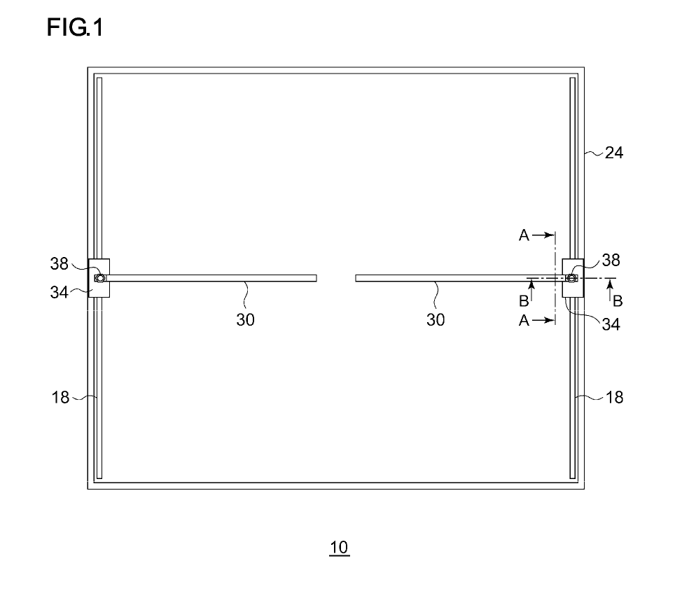

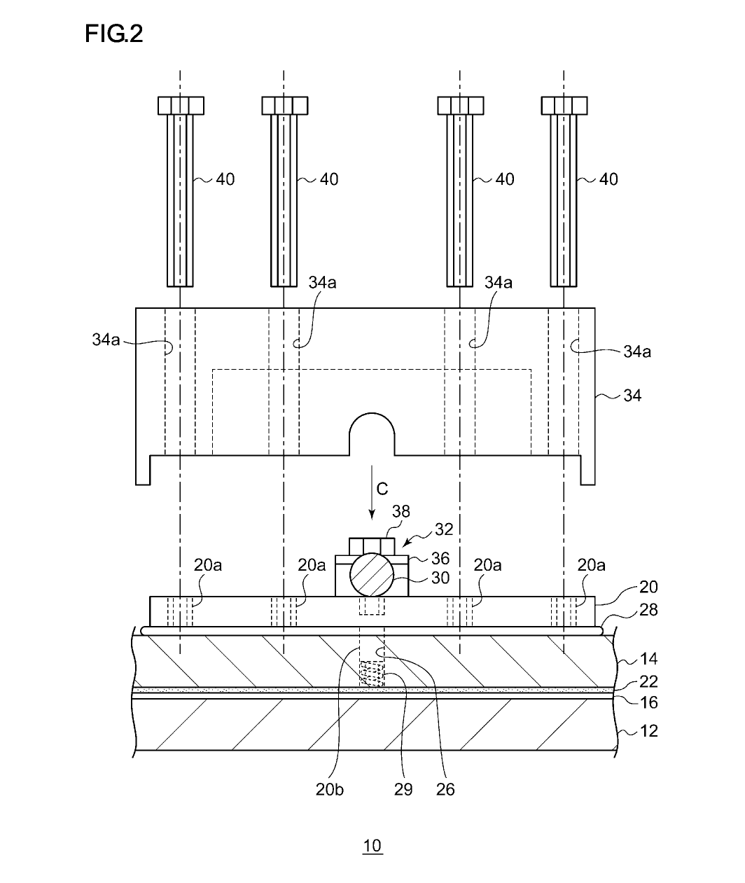

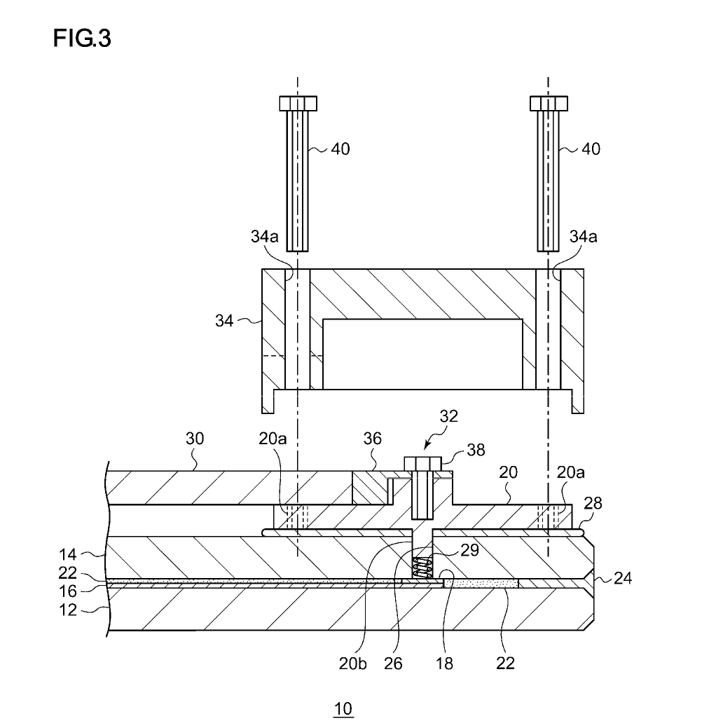

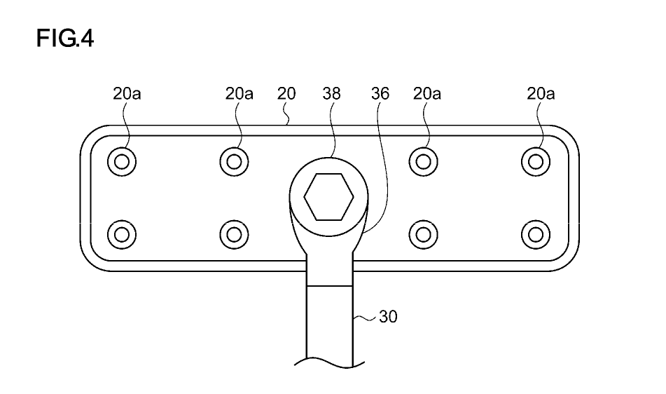

FIG. 1 is a plane view of a solar cell module, according to a first embodiment, as viewed from a back side opposite to a light receiving surface thereof. FIG. 2 is an exploded view of a cross section taken along the line A-A of FIG. 1 near a terminal box. FIG. 3 is an exploded view of a cross section taken along the line B-B of FIG. 1 near the terminal box. FIG. 4 is a top view of a current extraction member as viewed from an arrow C shown in FIG. 2. For clarity of the structure of a solar cell module 10, a filler 22 and a back-side member 14 are omitted in FIG. 1. Also, for clarity of the structure thereof, the dimensions of some of components in FIG. 1 to FIG. 4 are scaled differently from the actual dimensions.

The solar cell module 10 includes a translucent member 12, a back-side member 14, which serves as a protective member, a photovoltaic device 16, an electrode 18, which functions as a current-collecting wiring, a current extraction member 20, which is an electrically conductive member, a filler 22, and a sealing member 24.

The translucent member 12 is arranged at a light-receiving side of the solar cell module 10 and is made of glass, for instance. The back-side member 14 is provided in a position counter to the translucent member 12. For example, a cover glass or a back sheet is used for the back-side member 14. The photovoltaic device 16 is provided between the translucent member 12 and the back-side member 14. A detailed description is given later of the photovoltaic device 16.

The electrode 18 is provided between the translucent member 12 and the back-side member 14 and is connected to the photovoltaic device 16. Also, the electrodes 18 are placed parallel to two facing sides of the four sides of the solar cell module 10 (see FIG. 1), respectively. Here, these two facing sides thereof are located near the outer edge portions of the solar cell module 10. The current extraction member 20 is provided on an outer surface of the back-side member 14 and is so provided as to electrically conduct to the electrode 18. The current extraction member 20 is formed of a metal block, having a high conductivity, such as aluminum (Al) and copper (Cu).

The filler 22 is filled into a region where the translucent member 12 and the back-side member 14 face each other. Also, the sealing member 24 is placed at an outer edge of the solar cell module 10 and prevents water from entering into the solar cell module 10 through a gap (space) between the translucent member 12 and the back-side member 14.

The back-side member 14 has two through-holes 26. In the first embodiment, the two through-holes 26 are formed in positions partially overlapped with their respective electrodes 18, when viewed from a direction vertical to the surface of the back-side member 14.

The solar cell module 10 further includes a second sealing member 28 filled in a region where the current extraction member 20 and the back-side member 14 face each other. As illustrated in FIG. 2 and FIG. 3, the current extraction member 20 is secured to the back-side member 14 by the second sealing member 28 in such a manner as to cover the entire through-holes 26. The second sealing member 28 as used herein may be a material, such as silicone, used for the caulking, for instance, besides butyl rubber and ethylene vinyl acetate (EVA).

In the first embodiment, a conductive spring 29, serving as an elastic member, is held in the through-hole 26 formed between the current extraction member 20 and the electrode 18 in a state where the spring 29 is biased. Thereby, the current extraction member 20 and the electrode 18 are electrically conducted to each other.

As described above, in the solar cell module 10, the through-holes 26 formed in the back-side member 14 each functions as a path through which the electric energy, generated by the photovoltaic device 16, is extracted to the exterior, and the current extraction member 20 covers the whole through-holes 26. Also, a region, surrounding the through-holes 26, where the current extraction member 20 and the back-side member 14 face each other is filled with the second sealing member 28. With this structure, water or the like is less likely to infiltrate into an internal space of the solar cell module 10, surrounded by the translucent member 12 and the back-side member 14, from outside. As a result, the degradation of the photovoltaic device 16 is suppressed and the life of the solar cell module 10 is made longer.

Also, the current extraction member 20 is secured in such a manner as to cover the entire through-holes 26. Thus, the periphery of the through-holes 26 is strengthened. As a result, the solar cell module 10 is less likely to sag or bend at least in the vicinity of the through-holes 26. Should the solar cell module 10 warp or vibrate as a whole, a crack that may be triggered by the through-holes 26 will be less likely to occur because the periphery of the through-holes has been strengthened.

The solar cell module 10 further includes cables 30 connected to the current extraction member 20 for the purpose of outputting the electric energy, generated by the photovoltaic device 16, to exterior, a connection member 32 for connecting the cables 30 to the current extraction member 20 in a detachable manner, and a terminal box 34, serving as a casing, which is made of an insulating material. The terminal box 34 which covers the current extraction member 20 and the connection member 32 and which is fixed to the current extraction member 20 in a detachable manner.

The connection member 32 has a crimp terminal 36, which is crimped to one end of the cable 30, and a screw 38, with which the crimp terminal 36 is secured to the current extraction member 20. Also, the connection member 32 connects the current extraction member 20 and the cable 30 in a detachable manner.

The terminal box 34 has a plurality of through-holes 34a formed on top of it, and a plurality of screw holes 20a are formed, on top of the current extraction member 20, in positions corresponding to the through-holes 34a. Screws 40 are inserted into the through-holes 34a, then the tips of the screws 40 are screwed in the screw holes 20a and thereby the terminal box 34 is secured to the current extraction member 20 in a detachable manner.

As a result, even if the cables 30 and/or the terminal box 34 deteriorate because of the oxidation of metal by moisture or the like and because of the degradation of resin by ultraviolet rays, moisture or the like and thereby the desired performances thereof are no longer satisfied, such components can be replaced anew by removing the screw 38 and the screws 40. This allows the life of the solar cell module 10 as a whole to be extended.

The spring 29, which is an electrically conductive elastic member, is interposed between and held by the electrode 18 and the current extraction member 20. A raised portion 20b, whose outside diameter is slightly smaller than the inside diameter of the through-hole 26, is formed on the current extraction member 20 in such a manner that the raised portion 20b biases the spring 29 in the through-hole 26. Thus the raised portion 20b can protrude in the through-hole 26. Since the height of the raised portion 20b is set smaller than the depth of the through-hole 26, the spring 29 is in a state of being biased. In other words, the spring 29 is interposed between and held by the raised portion 20b and the electrode 18. Hence, even if a relative position relationship between the electrode 18 and the current extraction member 20 is deviated or changed due to the warping or vibration of the solar cell module 10, the electric conduction can be secured. Also, the risk of disconnection is low as compared to the normal wiring. As a result, the connection reliability is improved.

Also, the surface of the spring 29 is covered by a material whose electric conductivity is higher than that of the core of the spring 29. The material having a high electric conductivity is gold (Au), silver (Ag), copper or the like, for instance. Thereby, both the suitable elasticity and the appropriate conductivity in the spring 29 can be achieved. Note that the entire spring 29 may be formed of a material, having a high electric conductivity, such as gold (Au), silver (Ag) or copper.

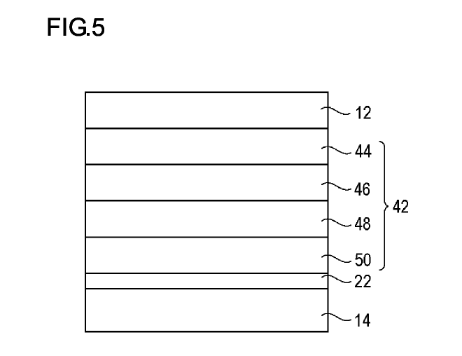

A description is now given of a structure of a photovoltaic element that constitutes the photovoltaic device 16. FIG. 5 is a diagram schematically showing the cross section of an exemplary photovoltaic element. A photovoltaic element 42 has a first electrode layer 44, a semiconductor layer 46, a transparent conductive film 48, and a second electrode layer 50. The first electrode layer 44, the semiconductor layer 46, the transparent conductive film 48, and the second electrode layer 50 are stacked on top of the translucent member 12, in this order, by subjecting them to a known laser patterning. Also, the filler 22 and the back-side member 14 are stacked on top of the second electrode layer 50.

The first electrode layer 44, which is formed on a surface of the translucent member 12, has electric conductivity and translucency. The first electrode layer 44 as used herein is a transparent conductive oxide (TCO), in particular, zinc oxide (ZnO) that is high in translucency, low in resistivity and is low priced.

The semiconductor layer 46 generates electric charges (electrons and positive holes) according to the incident light being entered from a first electrode layer 44 side. The semiconductor layer 46 as used herein may be an amorphous silicon semiconductor layer, having a p-i-n junction or p-n junction as a basic structure, a single-layered body made of a microcrystalline silicon semiconductor layer or a layered product of microcrystalline silicon semiconductor layers. The semiconductor layer 46 is structured such that an amorphous silicon semiconductor layer and a microcrystalline silicon semiconductor are stacked, in this order, starting to count from a first electrode layer 44 side. In the specification of this disclosure, the term “microcrystal” or “microcrystalline” means not only a completely crystallized state but also a state having a partially amorphous state.

The transparent conductive film 48 is formed on top of the semiconductor layer 46. The transparent conductive film 48 prevents the semiconductor layer 46 and the second electrode layer 50 from being alloyed with each other, so that the interconnection resistance between the semiconductor layer 46 and the second electrode layer 50 can be reduced.

The second electrode layer 50 is formed on top of the transparent conductive film 48. The second electrode layer 50 as used herein is a reflective metal such as silver (Ag). The transparent conductive film 48 and the second electrode layer 50 of each photovoltaic element 42 are in contact with the first electrode layers 44 of other adjacent photovoltaic elements 42. Thereby, one photovoltaic element 42 and another adjacent photovoltaic element 42 are electrically connected in series with each other. In this manner, the photovoltaic device 16 is configured by a plurality of photovoltaic elements 42.

### Second Embodiment

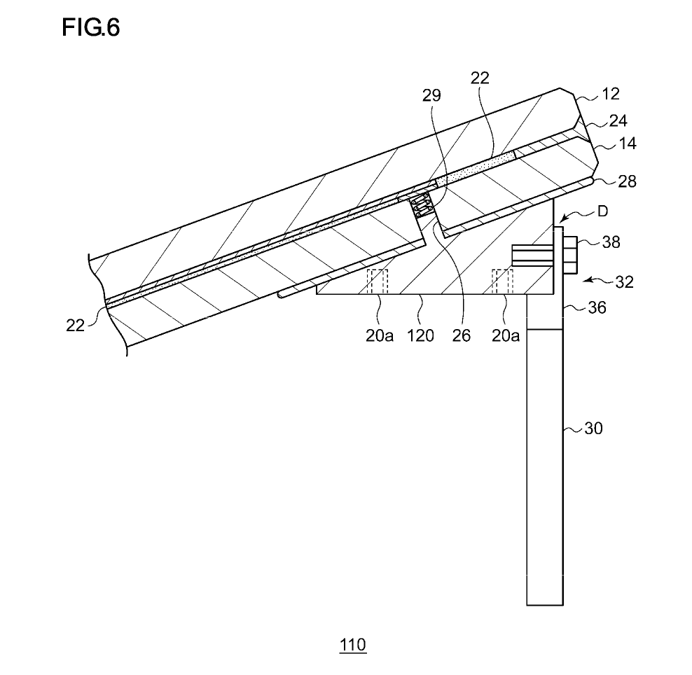

FIG. 6 is a partial cross-sectional view of a solar cell module, according to a second embodiment, near a current extraction member. A solar cell module 110, according to the second embodiment, as shown in FIG. 6, is markedly characterized by the feature in which the shape of a current extraction member 120 differs from that of the current extraction member 20 according to the first embodiment.

As shown in FIG. 6, the current extraction member 120 is secured to the back-side member 14 by the second sealing member 28 in such a manner as to cover the entire through-holes 26. Also, the current extraction member 120 is provided at an edge portion of the back-side member 14 and is arranged such that a region D, to which the connection member 32 comprised of the crimp terminal 36 and the screw 38 is connected, extends from the edge portion thereof toward the exterior of the solar cell module. This facilitates the replacement of the cables 30. Also, this makes it hard for the moisture to stay on, thereby suppressing the corrosion of the cables and the wiring.

### Third Embodiment

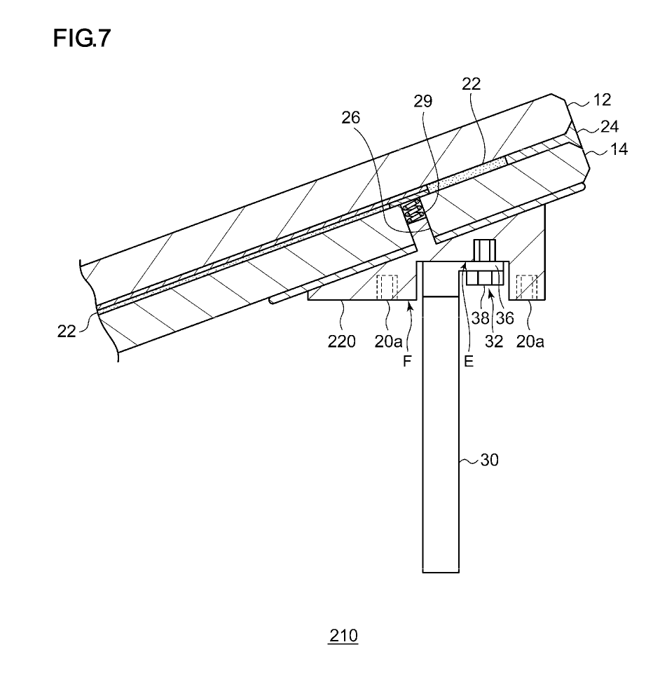

FIG. 7 is a partial cross-sectional view of a solar cell module, according to a third embodiment, near a current extraction member. A solar cell module 210, according to the third embodiment, as shown in FIG. 7, is markedly characterized by the feature in which the shape of a current extraction member 220 differs from that of the current extraction member 20 according to the first embodiment.

As shown in FIG. 7, the current extraction member 220 is secured to the back-side member 14 by the second sealing member 28 in such a manner as to cover the entire through-holes 26. The current extraction member 220 is formed in such a shape that a region E, to which the connection member 32 comprised of the crimp terminal 36 and the screw 38 is connected, is recessed from a region F that surrounds the region E. While the solar cell module 210 is in a state of being installed, the recessed region E is located below the back-side member 14 and the current extraction member 220 and is covered with the back-side member 14 and the current extraction member 220. This makes it hard for waterdrop and the like to stay on at a connection portion that connects the cables 30 to the current extraction member 220, thereby suppressing the corrosion of the cables and the wiring and improving the environmental durability.

Though no stands, which mount the solar cell modules, is shown in the second embodiment and the third embodiment, the solar cell module in each of the second embodiment and the third embodiment is installed at a slant on a stand with a direction extending horizontally in FIG. 6 and FIG. 7 defined as the horizontal direction. That is, the solar cell module in each of the second embodiment and the third embodiment is tilted relative to the horizontal direction.

### Fourth Embodiment

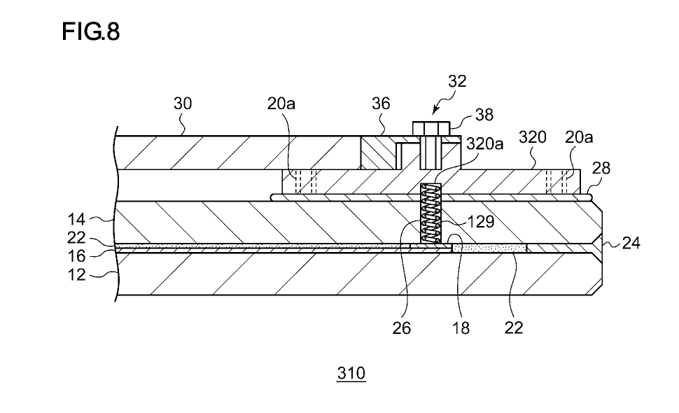

FIG. 8 is a partial cross-sectional view of a solar cell module, according to a fourth embodiment, near a current extraction member. A solar cell module 310, according to the third embodiment, as shown in FIG. 8, is markedly characterized by the feature in which the shape of a current extraction member 320 differs from that of the current extraction member 20 according to the first embodiment.

In the current extraction member 20 according to the first embodiment, the raised portion 20b is formed on the surface thereof facing the back-side member 14. In contrast to the first embodiment, in the current extraction member 320 according to the fourth embodiment, a recess 320a is formed on the surface thereof facing the back-side member 14. A conductive spring 129 is held inside a space, which is formed by the recess 320a and the through-hole 29, in a state where the spring 129 is biased. Thereby, the current extraction member 320 and the electrode 18 are electrically conducted to each other.

### Fifth Embodiment

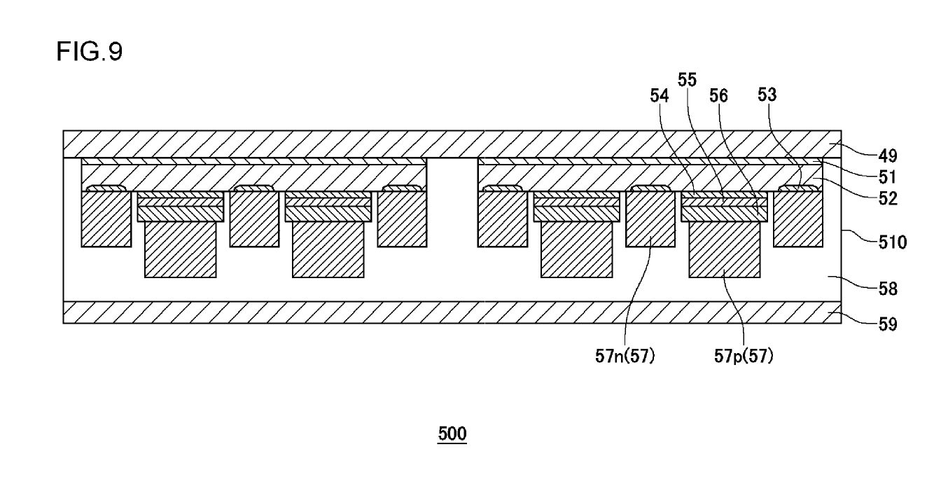

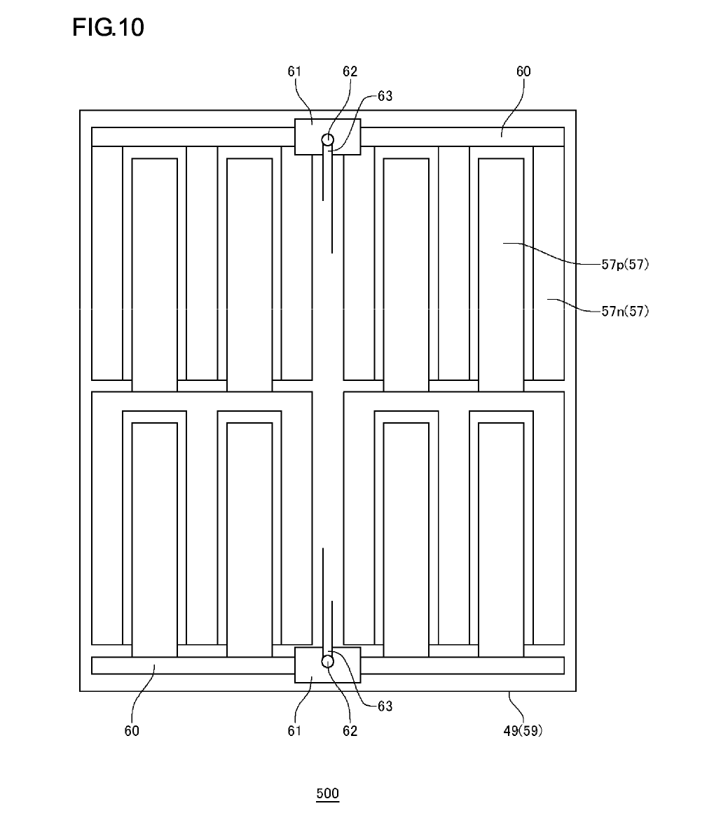

FIG. 9 is a cross-sectional view showing a structure of a solar cell module according to a fifth embodiment. FIG. 10 is a plane view showing a light-receiving surface of the solar cell module according to the fifth embodiment.

As shown in the cross-sectional view of FIG. 9 and the plane view of FIG. 10, a solar cell module 500 according to the fifth embodiment is configured by including a support substrate 49, a passivation layer 51, a base layer 52, a first conductive-type diffusion layer 53, an i-type layer 54, a second conductive-type layer 55, a transparent electrode layer 56, metallic layers 57, a filler 58, a back-side member 59, a conductive tab 60, a terminal box 61, a crimp terminal 62, and a cable 63. The passivation layer 51, the base layer 52, the first conductive-type diffusion layer 53, the i-type layer 54, the second conductive-type layer 55, the transparent electrode layer 56 and the metallic layers 57 constitute a photovoltaic element.

In the fifth embodiment, a photovoltaic device 510 is configured by including a plurality of photovoltaic elements. Also, the photovoltaic device 510 is configured by back-side bonding type photovoltaic elements, and the electrodes by which to extract the electric power generated by the photovoltaic elements to the exterior are provided only on a main surface opposite to the light receiving surface (hereinafter, this main surface will be referred to as a “back-side). However, the scope of application of the present invention is not limited the above case only, and the embodiments and modification are encompassed by the scope thereof as long as the photovoltaic device is configured such that a plurality of photovoltaic elements are arranged on the support substrate 49.

Here, the light-receiving surface indicates the main surface where the light mainly enters in the photovoltaic elements. More specifically, the light-receiving surface is a surface on which the majority of light entering into the photovoltaic elements is incident on.

The support substrate 49 mechanically supports the photovoltaic element and protects the semiconductor layer, included in the photovoltaic element, against an outside environment. Also, the support substrate 49 is placed on a light-receiving side of the photovoltaic element and therefore the support substrate 49 can transmit the light having a wavelength band used for the power generation at the photovoltaic element and can mechanically support each layer such as the base layer 52.

The passivation layer 51 is provided between the support substrate 49 and the base layer 52. The passivation layer 51 plays a role of, for instance, terminating the dangling bonds on the surface of the base layer 52, and suppresses the recombination of carries on the surface of the base layer 52. Provision of the passivation layer 51 can suppress the loss caused by the recombination of carriers on the surface of the base layer 52 at the light-receiving side of the photovoltaic element.

The passivation layer 51 is formed such that, for example, a silicon nitride (SiN) layer is included in the passivation layer 51, and the passivation layer 51 is more preferably of a stacked structure such that a silicon oxide (SiOx) layer and a silicon nitride (SiN) layer are stacked together. For example, a silicon oxide layer and a silicon nitride are stacked in sequence wherein the film thickness of the silicon oxide layer and the thickness of the silicon nitride are 30 nm and 40 nm, respectively. As will be discussed later, the support substrate 49 and the photovoltaic element are joined together with the passivation layer 51 held between the support substrate 49 and the photovoltaic element.

The base layer 52 is a crystalline semiconductor layer. Assume herein that a “crystalline” substance includes not only a single crystal but also a polycrystal where a multiplicity of crystal grains are gathered. The base layer 52 is a power generation layer of the photovoltaic element. Assume herein that the base layer 52 is doped with an n-type dopant and is an n-type crystalline silicon layer. The doping concentration of the base layer 52 is preferably about 10¹⁶/cm³.

The film thickness of the base layer 52 is such that the base layer 52 can sufficiently produce carriers as the power generation layer, and the film thickness thereof is desirably 0.5 μm or less.

The base layer 52 and the first conductive-type diffusion layer 53 form a first conductive-type contact region where a homo-junction occurs among the crystalline substances. The first conductive-type diffusion layer 53 is an n-type crystalline silicon layer doped with an n-type dopant. The first conductive-type diffusion layer 53 is a layer bonded to a metallic layer 57 (first electrode 57n), and the doping concentration of the first conductive-type diffusion layer 53 is higher than that of the base layer 52. The doping concentration of the first conductive-type diffusion layer 53 is preferably about 10¹⁹/cm³. The film thickness of the first conductive-type diffusion layer 53 is preferably as small as possible within a range where the contact resistance with a metal is sufficiently low, and the thickness thereof is preferably in a range between 0.1 μm to 2 μm (both inclusive), for instance.

The i-type layer 54 and the second conductive-type layer 55 are each formed as an amorphous-based semiconductor layer. An “amorphous-based” substance includes an amorphous phase or a microcrystalline phase where fine crystal grains are precipitated in the amorphous phase. In the fifth embodiment, the i-type layer 54 and the second conductive-type layer 55 are each formed of amorphous silicon containing hydrogen. The i-type layer 54 is a substantially intrinsic amorphous silicon layer. The second conductive-type layer 55 is an amorphous silicon layer doped with a p-type dopant. The doping concentration of the second conductive-type layer 55 is higher than that of the i-type layer 54. For example, the i-type layer 54 is intentionally not doped, and the doping concentration of the second conductive-type layer 55 is preferably about 10¹⁸/cm³. The film thickness of the i-type layer 54 is made smaller to suppress the absorption of light as much as possible, whereas the i-type layer 54 is made thick to the degree that the surface of the base layer 52 can be sufficiently passivated. More specifically, the thickness thereof is preferably in a range between 1 nm and 50 nm (both inclusive) and is 10 nm, for instance. Also, the film thickness of the second conductive-type layer 55 is made smaller to suppress the absorption of light as much as possible, whereas the second conductive-type layer 55 is made thick to the degree that the open voltage of the photovoltaic element is sufficiently high. For example, the thickness thereof is preferably in a range between 1 nm and 50 nm (both inclusive) and is 10 nm, for instance.

The transparent electrode layer 56 may preferably be made of at least one of transparent conductive oxides or made of a combination of two or more of transparent conductive oxides (TCO) in which tin oxide (SnO₂), zinc oxide (ZnO), indium tin oxide (ITO), or the like is doped with tin (Sn), antimony (Sb), fluorine (F), aluminum (Al) or the like. It is advantageous in that, among them, zinc oxide in particular is high in translucency, low in resistivity, and so forth. The film thickness of the transparent electrode layer 56 is preferably in a range between 10 nm and 500 nm (both inclusive) and is 100 nm, for instance.

The base layer 52, the i-type layer 54 and the second conductive-type layer 55 form a second conductive-type contact region where crystals and non-crystals are hetero-junctioned.

The metallic layers 57 are layers that form the electrodes provided on a back side of the photovoltaic elements. A metallic layer 57 is constituted by a conductive material such as a metal and is a material containing copper (Cu) or aluminum (Al), for instance. The metallic layers 57 include a first electrode 57n, which is connected to the first conductive-type diffusion layer 53, and a second electrode 57p, which is connected to the second conductive-type layer 55. The metallic layers 57 may further contain an electrolytic plating layer such as copper (Cu) or tin (Sn). However, this should not be considered as limiting and, for example, the metallic layers 57 may be formed of other metals, such as gold and silver, other conductive materials, or a combination thereof.

If the photovoltaic elements are modularized, the first electrodes 57n and the second electrodes 57p in a plurality of photovoltaic elements arranged side by side will be connected using the conductive tabs 60, and thereby the plurality of photovoltaic elements are connected in series or in parallel with each other. Further, the filler 58 is placed on the back sides of the photovoltaic elements so as to seal off the back-side member 59. The filler 58 may be a resin material such as ethylene-vinyl acetate (EVA) or polyimide. Also, the back-side member 59 may be glass or a resin material such as polyethylene terephthalate (PET), so that, for example, water can be prevented from entering into the power generation layer of the photovoltaic device 510 in the solar cell module 500.

In the solar cell module 500, the through-holes 26 (see FIG. 2) each functioning as the path through which the electric energy is extracted to the exterior are formed in the back-side member 59, and the whole through-holes 26 are covered with the current extraction member 20 (See FIG. 2 to FIG. 4).

The solar cell module 500 further include cables 63 each connected to the current extraction member 20 for the purpose of outputting the electric energy, generated by the photovoltaic device 510, to the exterior, crimp terminals 62, each of which connects the cable 63 to the current extraction member 20 in a detachable manner, and terminal boxes 61, each of which covers the current extraction member 20 and the connection member 32. Here, the terminal box 61 serves as a casing formed of an insulating material, and is fixed to the current extraction member 20 in a detachable manner.

As a result, even if the cables 63 and/or the terminal boxes 61 deteriorate because of the oxidation of metal by moisture or the like and because of the degradation of resin by ultraviolet rays, moisture or the like and thereby the desired performances thereof are no longer satisfied, such components can be replaced anew by removing the crimp terminal(s) 62. This allows the life of the solar cell module 500 as a whole to be extended.

The present invention has been described by referring to each of the above-described embodiments. However, the present invention is not limited to the above-described embodiments only, and those resulting from any combination of them or substitution as appropriate are also within the scope of the present invention. Also, it is understood by those skilled in the art that various modifications such as changes in the order of combination or processings made as appropriate in each embodiment or changes in design may be added to the embodiments based on their knowledge and the embodiments added with such modifications are also within the scope of the present invention.

The filler 22 as used in the above-described embodiments may be a material, such as silicone, used for the caulking, besides butyl rubber and ethylene vinyl acetate (EVA), a filled resin material such as polyvinylbutyral (PVB), an ethylene-based resin such as ethylene-ethyl-acrylate (EEA) copolymer, urethane, acrylic, or epoxy resin, for instance.

The first electrode layer 44 as used in the above-described embodiments may be preferably formed of one of or a plurality of layered product selected from metallic oxides that include zinc oxide (ZnO), tin oxide (SnO₂), indium oxide (In₂O₂), titanium oxide (TiO₂), zinc stannate (Zn₂SnO₄) and the like. Note that these metallic oxides may be doped with fluorine (F), tin (Sn), aluminum (Al), gallium (Ga), niobium (Nb) and the like.

What is claimed is:

1. A solar cell module comprising:
a translucent member disposed at a light-receiving side of the solar cell module;
a back-side member provided in such a position as to face the translucent member;
a photovoltaic device provided between the translucent member and the back-side member;
a current-collecting wiring connected to the photovoltaic device, the current-collecting wiring being provided between the translucent member and the back-side member;
a conductive member provided in such a manner as to electrically conduct to the current collecting wiring, the conductive member being provided on an outer surface of the back-side member; and
a sealing member filled in a region where the conductive element and the back-side member face each other,
wherein the back-side member has a through-hole, and
wherein the conductive member is fixed to the back-side member by the sealing member in such a manner as to cover the entire through-hole.

2. A solar cell module according to claim 1, further comprising:
an output cable connected to the conductive member for the purpose of outputting electric energy, generated by the photovoltaic device, to exterior;
a connection member configured to connect the output cable to the conductive member in a detachable manner; and
a casing configured to cover the conducive member and the connection member, the casing being fixed to the conductive member in a detachable manner.

3. A solar cell module according to claim 1, further comprising an electrically-conductive elastic member in the through-hole, the electrically-conductive elastic member configured to be held by the current-collecting wiring and the conductive member.

4. A solar cell module according to claim 2, further comprising an electrically-conductive elastic member in the through-hole, the electrically-conductive elastic member configured to be held by the current-collecting wiring and the conductive member.

5. A solar cell module according to claim 3, wherein the elastic member is a spring, and
wherein a surface of the spring is covered by a material whose electric conductivity is higher than that of a core of the spring.

6. A solar cell module according to claim 3, wherein the conductive member has a raised portion protruding in the through-hole, and
wherein the elastic member is held between the raised portion and the current-collecting wiring.
